(19) United States
(12) Patent Application Publication
(10) Pub. No.: US 2024/0395580 A1
(43) Pub. Date: Nov. 28, 2024

(54) MULTI-STATION PROCESSING MODULE AND REACTOR ARCHITECTURE

(71) Applicant: Lam Research Corporation, Fremont, CA (US)

(72) Inventor: Karl Frederick Leeser, West Linn, OR (US)

(21) Appl. No.: 18/696,299

(22) PCT Filed: Sep. 15, 2022
(86) PCT No.: PCT/US2022/043690

§ 371 Date: Mar. 27, 2024

Related U.S. Application Data
(60) Provisional application No. 63/253,932, filed on Oct. 8, 2021.

(51) Int. Cl. H01L 21/67; H01L 21/687

(52) U.S. Cl. CPC H01L 21/67167; H01L 21/67196; H01L 21/68707

(57) ABSTRACT

A multi-station processing module for processing substrates includes at least one substrate handoff station arranged in a first transfer plane. The at least one substrate handoff station is configured to perform a, handoff of at least one substrate of a plurality of substrates. The multi-station processing module further includes a, plurality of substrate processing stations arranged in a second transfer plane around a substrate transfer region. The second transfer plane is arranged parallel to and offset from the first, transfer plane. Each of the plurality of substrate processing stations is configured to process one or more of the plurality of substrates. The multi-station processing module further includes a robot arranged in the substrate transfer region. The robot is configured to move the one or more of the plurality of substrates between the first transfer plane and the second transfer plane during the handoff.

### CLAIM OF PRIORITY

This application claims the benefit of priority to U.S. Patent Application Ser. No. 63/253,932, filed on Oct. 8, 2021, which is incorporated by reference herein in its entirety.

### TECHNICAL FIELD

The subject matter disclosed herein generally relates to substrate processing systems, and more particularly to multi-station processing module (MSPM)-based substrate processing tools.

### BACKGROUND

Semiconductor substrate processing systems are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), resist removal, or other plasma-based processes. The substrate processing system may include one or more processing stations. In a substrate processing system, substrate handling can have a significant impact on cost and throughput. To increase throughput and reduce cost, the substrates need to be processed through different processing steps in the most efficient manner and with minimal or no contamination. Existing substrate processing systems, however, are associated with certain processing inefficiencies. Example processing inefficiencies include lack of station isolation, presence of station cross-talk (e.g., thermally or from coupled plasmas), process non-uniformities resulting from using an integrated spindle-transfer mechanism, etc.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

One general aspect of the disclosure is a multi-station processing module for processing substrates. The multi-station processing module includes at least one substrate handoff station arranged in a first transfer plane. The at least one substrate handoff station is configured to perform a handoff of at least one substrate of a plurality of substrates. The multi-station processing module further includes a plurality of substrate processing stations arranged in a second transfer plane around a substrate transfer region. The second transfer plane is arranged parallel to and offset from the first transfer plane. Each of the plurality of substrate processing stations is configured to process one or more of the plurality of substrates. The multi-station processing module further includes a robot arranged in the substrate transfer region. The robot is configured to move the one or more of the plurality of substrates between the first transfer plane and the second transfer plane during the handoff.

Another general aspect includes a substrate processing tool including a vacuum transfer module and a plurality of multi-station processing modules for processing substrates received from the vacuum transfer module. The plurality of multi-station processing modules are arranged along an outside perimeter of the vacuum transfer module. Each of the plurality of multi-station processing modules includes at least one substrate handoff station arranged in a first transfer plane. The at least one substrate handoff station is configured to perform a handoff of at least one substrate of a plurality of substrates received from the vacuum transfer module. Each of the plurality of multi-station processing modules further includes a plurality of substrate processing stations arranged in a second transfer plane around a substrate transfer region. Each of the plurality of substrate processing stations is configured to process one or more of the plurality of substrates. Each of the plurality of multi-station processing modules further includes a robot arranged in the substrate transfer region. The robot is configured to move the one or more of the plurality of substrates between the at least one substrate handoff station and the plurality of substrate processing stations during the handoff.

An additional general aspect includes a multi-station processing module for processing substrates, the multi-station processing module includes at least one substrate handoff station arranged in a first transfer plane. The at least one substrate handoff station is configured to perform a handoff of at least one substrate of a plurality of substrates. The multi-station processing module further includes a plurality of substrate processing stations arranged in a second transfer plane around a substrate transfer region. Each of the plurality of substrate processing stations is configured to process one or more of the plurality of substrates using a substantially axisymmetric body portion. The multi-station processing module further includes a robot arranged in the substrate transfer region. The robot is configured to move the one or more of the plurality of substrates between the at least one substrate handoff station and the plurality of substrate processing stations during the handoff.

### BRIEF DESCRIPTION OF THE DRAWINGS

Various ones of the appended drawings merely illustrate example embodiments of the present disclosure and cannot be considered as limiting its scope.

FIG. 1 illustrates a top view of a multi-station processing module (MSPM) using multiple transfer planes, according to some example embodiments.

FIG. 2 illustrates a rear view of the MSPM of FIG. 1, according to some example embodiments.

FIG. 3 illustrates a side view of the MSPM of FIG. 1, according to some example embodiments.

FIG. 4 illustrates a perspective view of the MSPM of FIG. 1, according to some example embodiments.

FIG. 5 illustrates a substrate processing tool including a cluster tool arrangement based on the MSPM of FIG. 1, according to some example embodiments.

FIG. 6 illustrates a substrate processing tool including a second cluster tool arrangement based on the MSPM of FIG. 1, according to some example embodiments.

FIG. 7 illustrates a substrate processing tool including a third cluster tool arrangement based on the MSPM of FIG. 1, according to some example embodiments.

FIG. 8, FIG. 9, FIG. 10, and FIG. 11 illustrate MSPMs using a single transfer plane, according to some example embodiments.

FIG. 12 illustrates a multi-level MSPM using multiple transfer planes with handoff stations being arranged higher than substrate processing stations, according to some example embodiments.

FIG. 13 illustrates a vacuum chamber, such as an etching chamber, for manufacturing substrates, which can be used in an MSPM disclosed herein, according to some example embodiments.

FIG. 14 is a block diagram illustrating an example of a machine upon which one or more example method embodiments may be implemented, or by which one or more example embodiments may be controlled.

### DETAILED DESCRIPTION

The description that follows includes systems, methods, and techniques that embody illustrative embodiments of the present invention. Examples merely typify possible variations. Unless explicitly stated otherwise, components and functions are optional and may be combined or subdivided. Additionally, operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

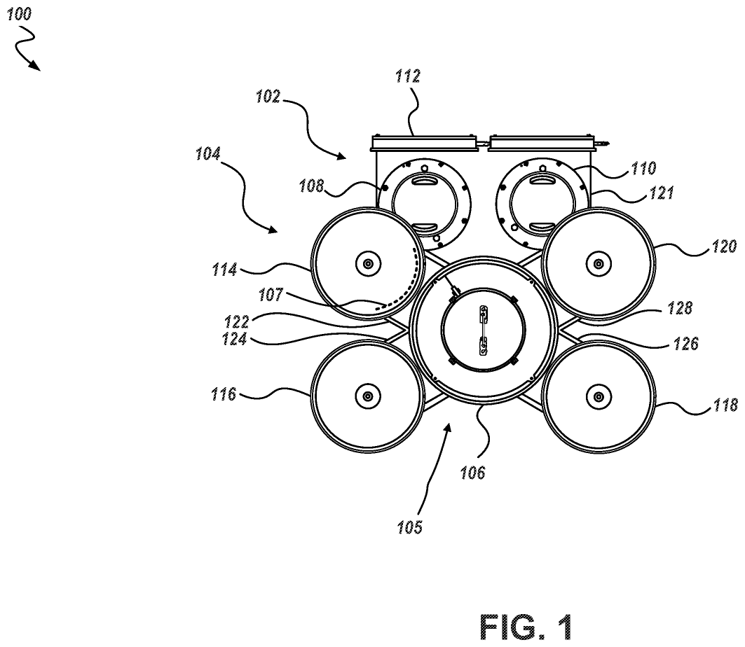

As used herein, the term “plasma-based process” can comprise a deposition process, an etch process, or a multi-step process (e.g., a deposition process followed by an etch process). As used herein, the term “reactor,” “reactor arrangement,” or “constellation reactor” can comprise a cluster tool arrangement for processing substrates, including an arrangement of multi-station processing modules (MSPMs) where each MSPM is configured to process multiple substrates. Example MSPMs are discussed in connection with FIG. 1-FIG. 12.

The disclosed MSPM may be used to overcome deficiencies associated with some existing substrate processing modules, such as lack of processing station isolation, the existence of station-to-station crosstalk (e.g., thermal crosstalk as well as crosstalk from couples plasmas), non-uniformity resulting from an integrated spindle transfer mechanism, prolonged processing time due to synchronous substrate transfer, and reduced service access due to the size of the spindle transfer mechanism housing. More specifically, the disclosed MSPM includes multiple substrate processing stations and substrate handoff stations, with each processing station being housed in its axisymmetric body portion. In some aspects, the multiple substrate processing stations and substrate handoff stations are configured at different levels (or transfer planes) or the same level. Additionally, the MSPM includes a robot (e.g., a vacuum robot), instead of a spindle mechanism, to handle the asynchronous transfer of substrates between the substrate handoff stations and the substrate processing stations.

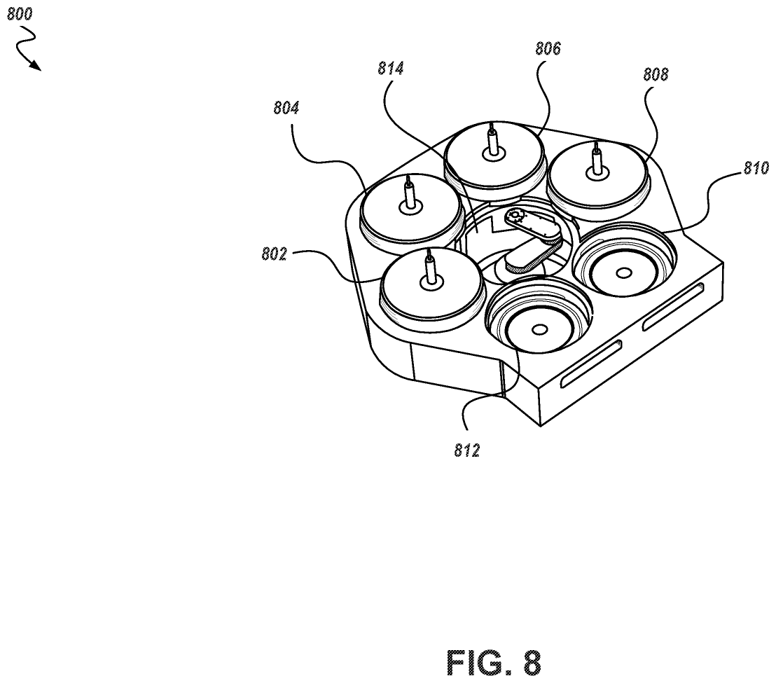

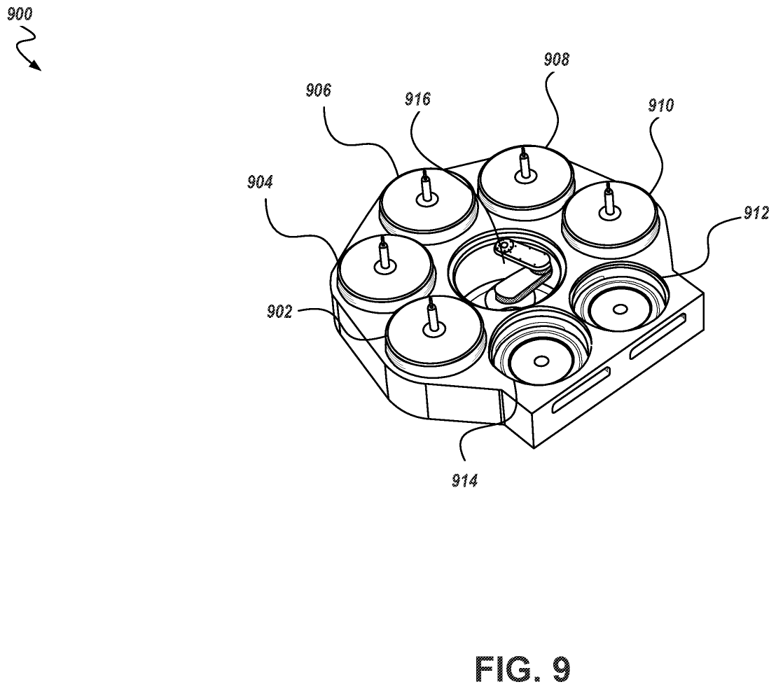

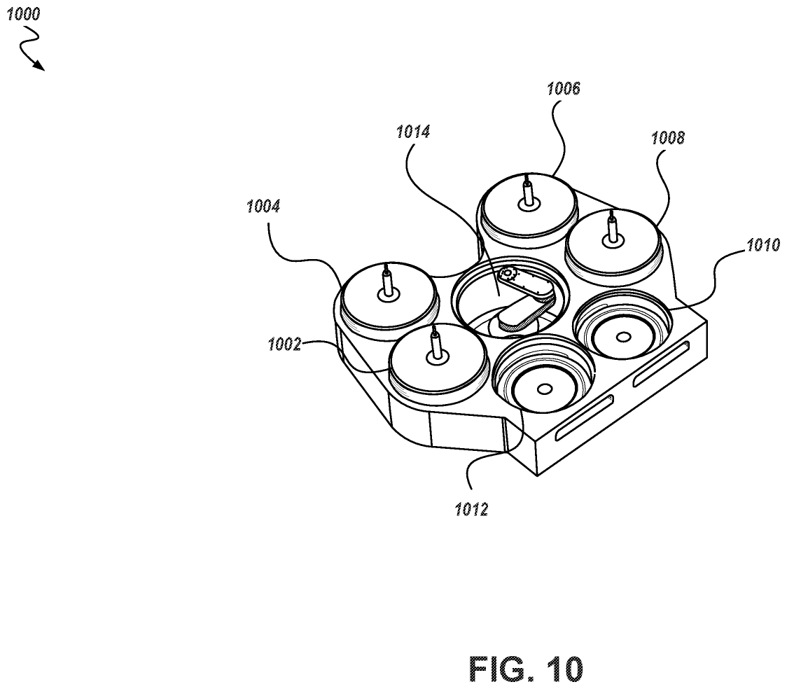

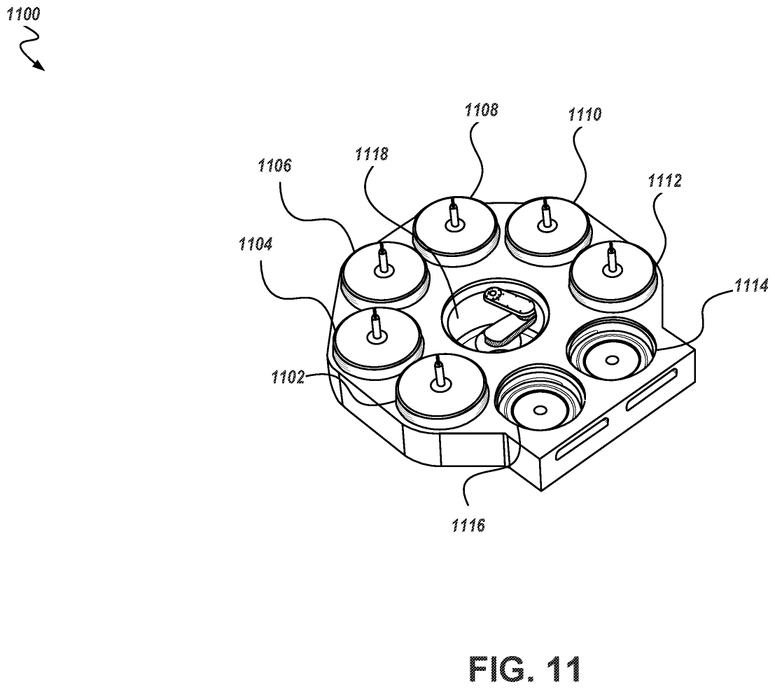

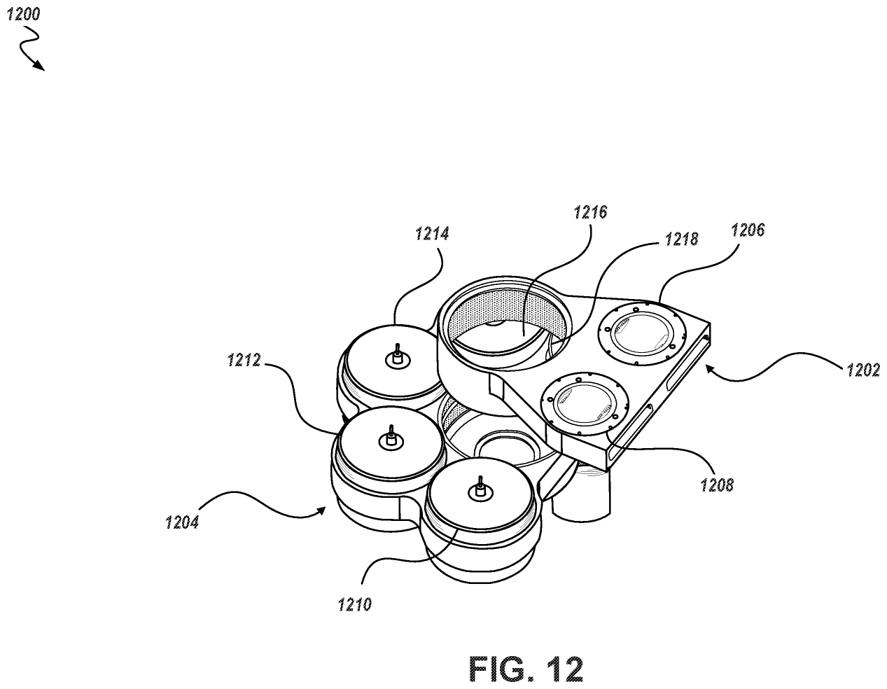

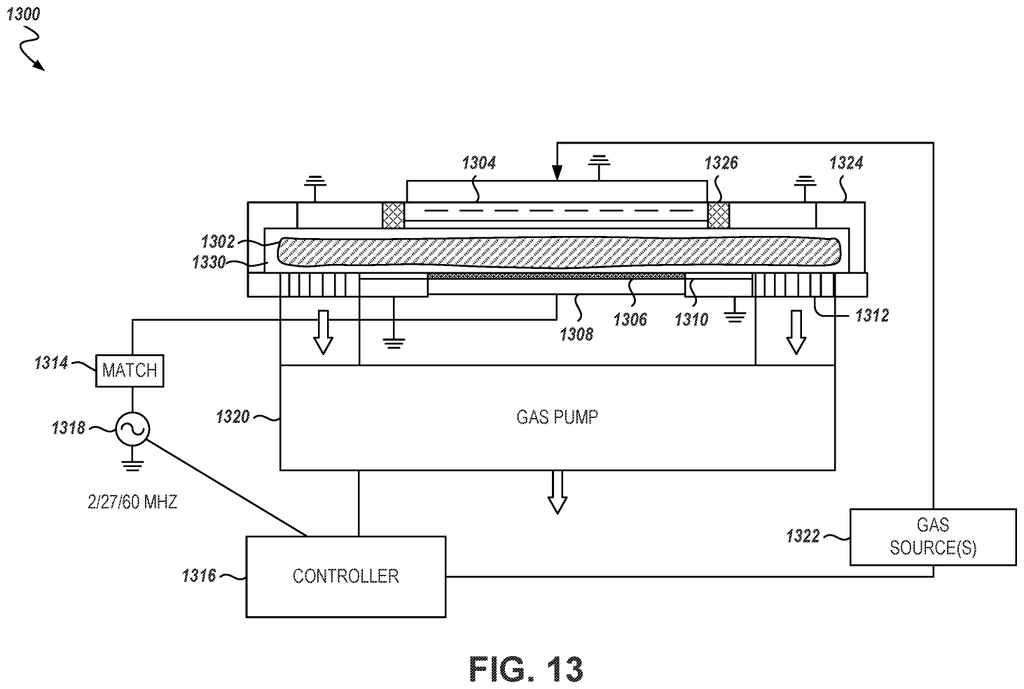

FIG. 1-FIG. 4 illustrates a multi-level MSPM with the substrate handoff stations being at a lower transfer plane than the substrate processing stations. FIG. 5-FIG. 7 illustrate different substrate processing tools (e.g., cluster tool arrangements) based on the MSPM of FIG. 1. FIG. 8-FIG. 11 illustrate different single-level MSPMs with the substrate handoff stations being at the same transfer plane (or level) as the substrate processing stations. FIG. 12 illustrates a multi-level MSPM with the substrate handoff stations being at a higher transfer plane than the substrate processing stations. FIG. 13 is an example vacuum chamber that may be used as a substrate processing station within the disclosed MSPMs.

FIG. 1 illustrates a top view of a multi-station processing module (MSPM) 100 using multiple transfer planes, according to some example embodiments. Referring to FIG. 1, the MSPM 100 includes at least one substrate handoff station (e.g., substrate handoff stations 108 and 110) arranged in a first transfer plane (or a first level) 102 and configured to perform a handoff of at least one substrate of a plurality of substrates. The MSPM 100 further includes a plurality of substrate processing stations (e.g., substrate processing stations 114, 116, 118, and 120) arranged in a second transfer plane (or a second level) 104 around a substrate transfer region 105 (e.g., symmetrically or asymmetrically). The substrate processing stations 114, 116, 118, and 120 are configured to process one or more of the plurality of substrates. The MSPM 100 further includes a robot 106 (e.g., a vacuum robot) arranged in the substrate transfer region 105. Robot 106 is configured to move the one or more of the plurality of substrates between the first transfer plane 102 and the second transfer plane 104 during the hand-off. The robot 106 may include at least radial position control in addition to theta position control.

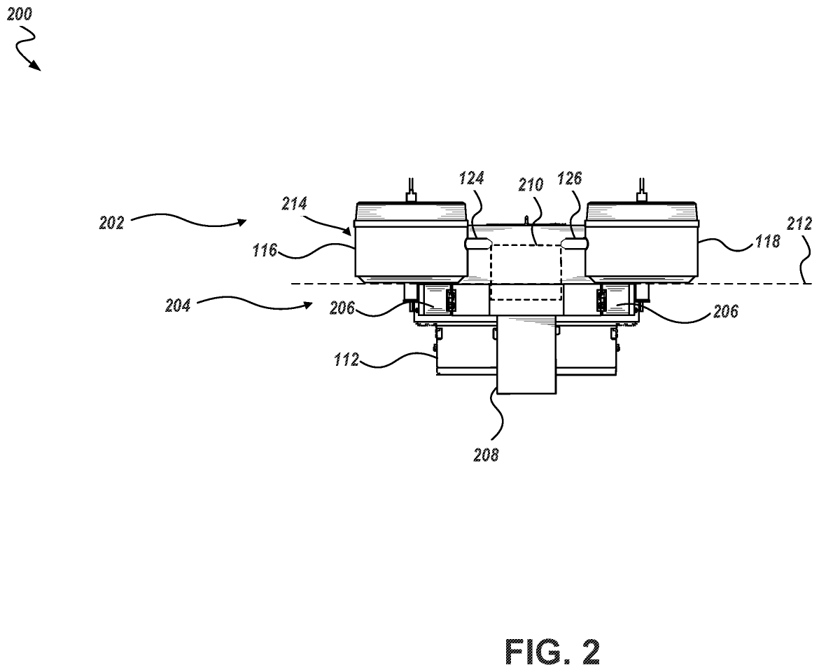

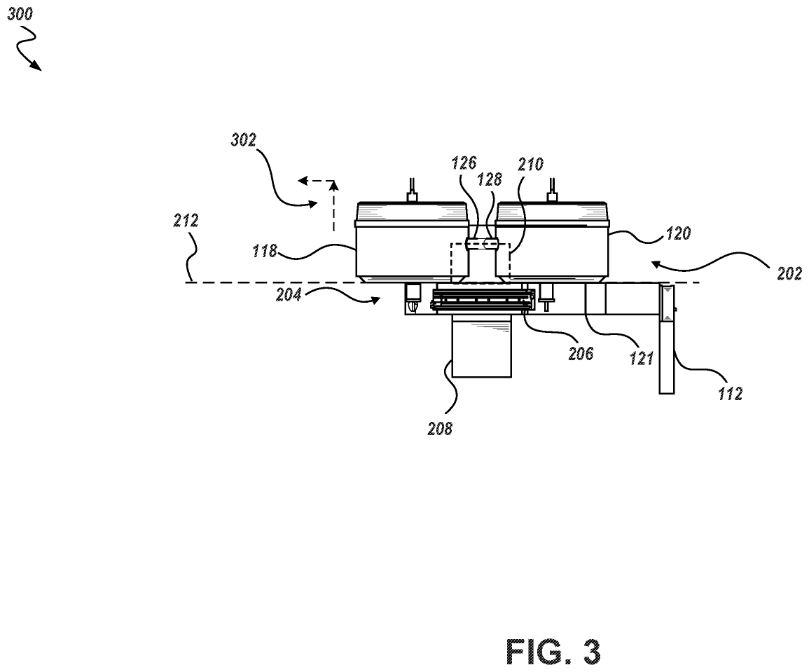

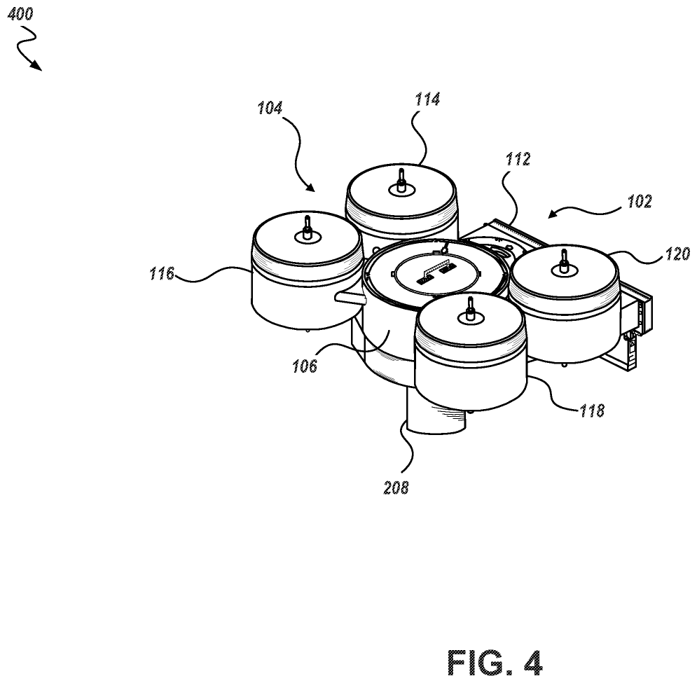

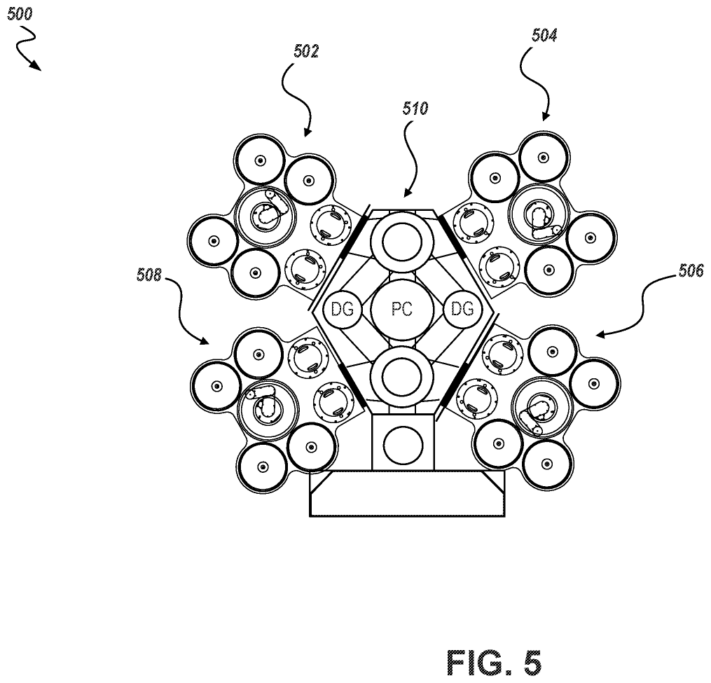

FIG. 2, FIG. 3, and FIG. 4 provide additional views of the MSPM 100. For example, FIG. 2 illustrates a rear view 200 of the MSPM 100, FIG. 3 illustrates a side view 300 of the MSPM 100, and FIG. 4 illustrates a perspective view 400 of the MSPM of FIG. 1, according to example embodiments.

In reference to FIGS. 1-4, the substrate processing stations 114-120 may be configured in an upper MSPM section 202 within the second transfer plane 104 of the MSPM 100. The substrate handoff stations 108, 110 may be configured in a lower MSPM section 204 within the first transfer plane 102 of the MSPM 100. As illustrated in FIG. 2, the upper MSPM section 202 and the lower MSPM section 204 are disposed on opposite sides of the separation plane 212.

The upper MSPM section 202 includes the substrate processing stations 114, 116, 118, and 120, and corresponding substrate passthrough slots 122, 124, 126, and 128. The substrate passthrough slots 122-128 connect the corresponding substrate processing stations with a vertical passageway 210 within the substrate transfer region 105.

The lower MSPM section 204 includes the substrate handoff stations 108 and 110, a substrate passthrough slot 121, an isolation valve 112, a sliding arrangement 206, and a robot enclosure 208. The isolation valve isolates the MSPM 100 from an external robot (e.g., as may be used in connection with a vacuum transfer module) of a substrate processing tool (e.g., a cluster tool arrangement of MSPMs, such as illustrated in connection with FIGS. 5-7). The substrate passthrough slot 121 connects the substrate handoff stations 108 and 110 with the vertical passageway 210 within the substrate transfer region 105. In this regard, the vertical passageway 210 extends between the lower MSPM section 204 in the first transfer plane 102 and the upper MSPM section 202 in the second transfer plane 104, allowing the robot 106 to move substrates between the substrate handoff stations 108, 110, and the substrate processing stations 114-120 during handoff.

The robot enclosure 208 is configured to house the robot actuators and control circuitry of robot 106. Additionally, the robot enclosure 208 houses linear slides (not referenced in FIGS. 1-4) performing a vertical movement (e.g., within the vertical passageway 210) of the robot 106, such as when transferring/moving substrates between the lower MSPM section 204 in the first transfer plane 102 and the upper MSPM section 202 in the second transfer plane 104.

In some embodiments, the sliding arrangement 206 is configured to move the upper MSPM section 202 (or the second transfer plane 104) in a vertical (e.g., axial) and/or horizontal (e.g., azimuthal) direction in relation to the lower MSPM section 204 (or the first transfer plane 102) for providing service access to components of the MSPM 100. An example movement trajectory 302 is illustrated in FIG. 3, but other movement trajectories are also possible.

In some embodiments, each of the substrate processing stations 114-120 can be manufactured using a substantially axisymmetric body portion (e.g., body portion 214 of the substrate processing station 116). More specifically, as illustrated in FIGS. 1-4, each of the substrate processing stations 114-120 can be manufactured with substantially cylindrical (and axisymmetric) body portions that are substantially isolated from each other and are connected to the substrate transfer region 105 via the corresponding substrate passthrough slots 122-128. In this regard, the substrate processing stations 114-120 may also be referred to as “joined components” forming the upper MSPM section 202.

In operation, substrates may be deposited (e.g., by a vacuum transfer module of a substrate processing tool that includes the MSPM 100) at the substrate handoff stations 108 and 110. The robot 106 is configured to horizontally move the substrates within the substrate passthrough slot 121, from the substrate handoff stations to the vertical passageway 210 of the substrate transfer region 105. Robot 106 vertically moves the substrates from the first transfer plane to at least one of the substrate processing stations 114-120 in the second transfer plane 104 for processing. The vertical movement may use the vertical passageway 210 and at least one of the substrate passthrough slots 122-128. In some embodiments, each of the substrate processing stations 114-120 may include a vacuum chamber (e.g., vacuum chamber 1300 of FIG. 13) used for processing a substrate (e.g., using a deposition or an etching process). In some embodiments, different processes (or different stages of a process) may be performed (e.g., independently of each other) in the substrate processing stations 114-120. After substrates have been processed, robot 106 can transfer substrates between the substrate processing stations 114-120, or to the substrate handoff stations 108 and 110 (if no additional processing is required).

In some embodiments, the MSPM 100 may use one or more dedicated load stations (e.g., the substrate handoff stations 108 and 110) to enable high-speed swaps with a vacuum transfer module. Once loaded/unloaded, the centralized vacuum robot of the MSPM (e.g., robot 106) can transfer substrates asynchronously to the individual substrate processing stations. Such transfer enables significantly reduced waiting time and, therefore, higher processing station utilization.

Some example benefits of using the disclosed configurations of the MSPM 100 include the following: (a) reduction in the overall processing module size (e.g., by using two offset transfer planes); (b) efficient fabrication of the processing stations (e.g., the substantially axisymmetric body portions may be fabricated from a large diameter aluminum pipe) characterized by only thermal anomaly resulting from station cross-talk via the passthrough slots: (c) using individual station lids for the substrate processing stations (instead of a single module lid which results in stations cross-talk and process inefficiencies); (d) efficient process kit design using co-axial parts for servicing the axisymmetric body portions of the substrate processing stations; and (e) efficient configuration of substrate processing tools as cluster tool arrangements of multiple MSPMs (e.g., as illustrated in FIGS. 5-7).

Even though FIGS. 1-4 illustrate the MSPM 100 configured with a first transfer plane 102 that is offset from (and is lower than) the second transfer plane 104, the disclosure is not limited in this regard. In some embodiments, the first and second transfer planes of the MSPM are coincident (or coplanar) with each other. For example (and as illustrated in FIGS. 8-11), an MSPM may be configured with a different number of substrate handoff stations and substrate processing stations that are all disposed at the same transfer plane. In yet different embodiments (e.g., as illustrated in FIG. 12), an MSPM can be configured with a first transfer plane (with one or more substrate handoff stations) that is offset from (and is higher than) the second transfer plane 104 (with a plurality of substrate processing stations).

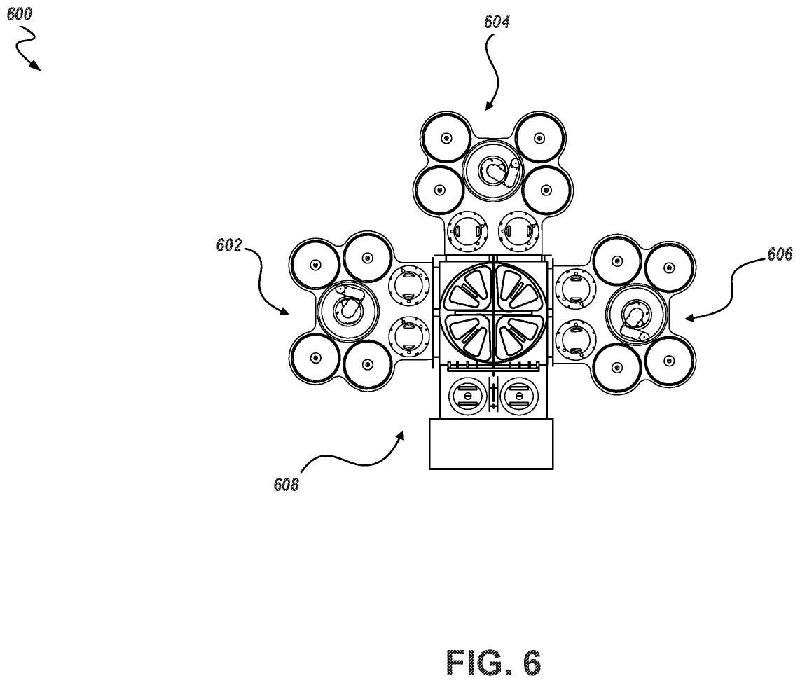

Even though FIGS. 1-4 illustrate the MSPM 100 to include two substrate handoff stations 108 and 110 and four substrate processing stations 114-120, the disclosure is not limited in this regard and a different number of substrate handoff stations and substrate processing stations may be used in a single MSPM. In some embodiments, the MSPM 100 may include no substrate handoff stations, and the robot 106 may be configured to perform direct handoff to a vacuum transfer module (e.g., vacuum transfer module 608 of substrate processing tool 600 of FIG. 6).

In some embodiments, the substrate processing stations 114-120 can be further isolated from each other using at least one purging gas curtain. For example and as illustrated in FIG. 1, a purging gas curtain 107 can be used to isolate the substrate passthrough slot 122. Isolating the substrate passthrough slot 122 can result in improved isolation of substrate processing station 114 from the remaining substrate processing stations of the MSPM 100.

In some embodiments, each of the substrate handoff stations 108 and 110 is configured to perform the handoff during the processing of the substrates by at least one of the substrate processing stations 114-120. In some embodiments, each of the plurality of substrate processing stations 114-120 includes a corresponding plurality of substantially axisymmetric body portions (e.g., similar to axisymmetric body portion 214 of the substrate processing station 116). In some embodiments, the substantially axisymmetric body portions are isolated from each other via at least one purging gas curtain. In some embodiments, the MSPM 100 includes a sliding arrangement 206 disposed in the first transfer plane 102. The sliding arrangement 206 may be configured to move the second transfer plane 104 in a vertical and/or horizontal direction in relation to the first transfer plane 102.

In some embodiments, the substrate handoff stations can be configured as a substrate handoff station (e.g., station 108) and a pre-processing station (e.g., station 110) arranged in the first transfer plane 102. The substrate handoff station 110 may be configured to perform the handoff of substrates, and the pre-processing station 110 is configured to perform pre-processing of substrates. For example, the pre-processing may include at least one of degassing, pre-cleaning, or pre-heating of the substrates.

In some embodiments, the substrate handoff stations can be configured as a pre-processing station (e.g., station 108) and a post-processing station (e.g., station 110). The pre-processing station 108 is configured to perform pre-processing of the plurality of substrates (e.g., degassing, pre-cleaning, or pre-heating) of substrates. The post-processing station 110 is configured to perform post-processing of the substrates (e.g., cooling down or annealing).

In some embodiments, the plurality of substrates processed by the MSPM 100 includes a plurality of semiconductor wafers. In some embodiments, the substrate processing stations 114-120 are configured to process the substrates while performing the same deposition or etching process or different deposition or etching processes. In some embodiments, the substrate processing stations 114-120 are symmetrically arranged around the substrate transfer region 105. In some embodiments, the substrate processing stations 114-120 are asymmetrically arranged around the substrate transfer region 105.

In some embodiments, the substrate processing stations 114-120 need not run the same process. For example, the substrate processing stations 114-120 may be used for applying different films or may be used for applying nucleation layers or liner films in one substrate processing station followed by a bulk film deposition in a subsequent substrate processing station. Alternatively, the substrate processing stations 114-120 may be used for applying the same film but based on different chemistries. Alternatively, the substrate processing stations 114-120 may be used for the same or different films deposited at different temperatures or different pressures. One skilled in the art will recognize that many sequenced processes are of interest for which the disclosed reactor arrangements may be used.

FIG. 5 illustrates a substrate processing tool 500 including a cluster tool arrangement based on the MSPM of FIG. 1, according to some example embodiments. Referring to FIG. 5, the substrate processing tool 500 includes a vacuum transfer module 510 and a plurality of multi-station processing modules (MSPMs) 502, 504, 506, and 508 for processing substrates received from the vacuum transfer module 510. The plurality of MSPMs 502-508 are arranged along an outside perimeter of the vacuum transfer module 510. Each of the plurality of MSPMs 502-508 may be similar to MSPM 100 of FIG. 1.

In some embodiments, each of the MSPMs 502-508 includes at least one substrate handoff station arranged in a first transfer plane. The at least one substrate handoff station is configured to perform a handoff of at least one substrate of a plurality of substrates received from the vacuum transfer module 510. Each of the MSPMs 502-508 further includes a plurality of substrate processing stations arranged in a second transfer plane around a substrate transfer region. Each of the plurality of substrate processing stations is configured to process one or more of the plurality of substrates. Each of the MSPMs 502-508 further includes a robot arranged in the substrate transfer region. The robot is configured to move the one or more of the plurality of substrates between the at least one substrate handoff station and the plurality of substrate processing stations during the handoff.

In some embodiments, the vacuum transfer module 510 further includes a second robot. The second robot is configured to perform a handoff of the at least one substrate to the at least one substrate handoff station. The second robot is also configured to retrieve the at least one substrate from the at least one substrate handoff station after processing the at least one substrate by at least one of the plurality of substrate processing stations.

In some embodiments, the vacuum transfer module 510 further includes at least one pre-processing station and at least one post-processing station. At least one pre-processing station is configured to perform pre-processing of the plurality of substrates. The pre-processing includes degassing (e.g., indicated as DG in FIG. 5), pre-cleaning (e.g., indicated as PC in FIG. 5), or pre-heating of the plurality of substrates. In some embodiments, at least one post-processing station is configured to perform post-processing of the plurality of substrates (e.g., cooling down or annealing).

In some embodiments, the first transfer plane and the second transfer plane are coincident with each other. In some embodiments, the second transfer plane is arranged parallel to and offset from the first transfer plane.

FIG. 6 illustrates a substrate processing tool 600 including a second cluster tool arrangement based on the MSPM of FIG. 1, according to some example embodiments. Referring to FIG. 6, the substrate processing tool 600 includes a vacuum transfer module 608 and a plurality of MSPMs 602, 604, and 606 for processing substrates received from the vacuum transfer module 608. The plurality of MSPMs 602-606 are arranged along an outside perimeter of the vacuum transfer module 608. Each of the plurality of MSPMs 602-606 may be similar to MSPM 100 of FIG. 1.

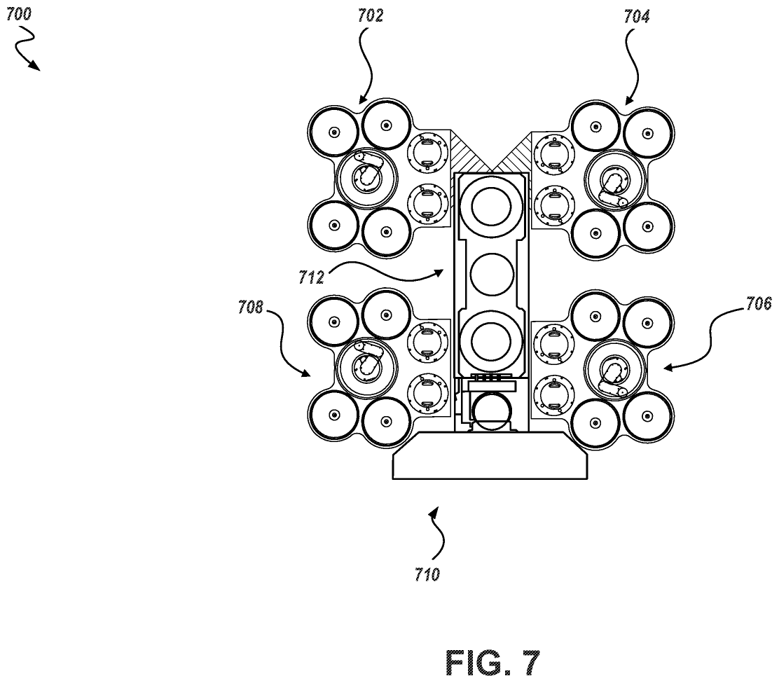

FIG. 7 illustrates a substrate processing tool 700 including a third cluster tool arrangement based on the MSPM of FIG. 1, according to some example embodiments. Referring to FIG. 7, the substrate processing tool 700 includes a vacuum transfer module 710 and a plurality of MSPMs 702, 704, 706, and 708 for processing substrates received from the vacuum transfer module 710. The plurality of MSPMs 702-708 are arranged along an outside perimeter of the vacuum transfer module 710. Each of the plurality of MSPMs 702-708 may be similar to MSPM 100 of FIG. 1. In some embodiments, the vacuum transfer module includes one or more substrate transfer stations 710 used for transferring substrates to and from the MSPMs 702-708.

FIG. 8, FIG. 9, FIG. 10, and FIG. 11 illustrate MSPMs using a single transfer plane for the substrate handoff stations and the substrate processing stations., according to some example embodiments. Referring to FIG. 8, there is illustrated a 6-station MSPM 800 using a single transfer plane for the substrate handoff stations and the substrate processing stations. For example, the MSPM 800 includes substrate handoff stations 810 and 812 disposed on the same level (or the same transfer plane) as substrate processing stations 802, 804, 806, and 808 as well as robot 814.

Referring to FIG. 9, there is illustrated a 7-station MSPM 900 using a single transfer plane for the substrate handoff stations and the substrate processing stations. For example, the MSPM 900 includes substrate handoff stations 912 and 914 disposed on the same level (or the same transfer plane) as substrate processing stations 902, 904, 906, 908, and 910 as well as robot 916.

Referring to FIG. 10, there is illustrated a 6-station MSPM 1000 using a single transfer plane for the substrate handoff stations and the substrate processing stations. For example, the MSPM 1000 includes substrate handoff stations 1010 and 1012 disposed on the same level (or the same transfer plane) as substrate processing stations 1002, 1004, 1006, and 1008 as well as robot 1014.

Referring to FIG. 11, there is illustrated an 8-station MSPM 1100 using a single transfer plane for the substrate handoff stations and the substrate processing stations. For example, the MSPM 1100 includes substrate handoff stations 1114 and 1116 disposed on the same level (or the same transfer plane) as substrate processing stations 1102, 1104, 1106, 1108, 1110, and 1112 as well as robot 1118.

FIG. 12 illustrates a multi-level MSPM 1200 using multiple transfer planes with handoff stations being arranged higher than substrate processing stations, according to some example embodiments. Referring to FIG. 12, the multi-level MSPM 1200 is a 7-station MSPM using multiple transfer planes 1202 and 1204. More specifically, the MSPM 1200 includes substrate handoff stations 1206 and 1208 disposed in the first transfer plane 1202, and substrate processing stations 1210, 1212, 1214, 1216, and 1218 disposed of in the second transfer plane 1204 which is lower than the first transfer plane 1202.

FIG. 13 illustrates a vacuum chamber 1300, such as an etching chamber, for manufacturing substrates, which can be used in an MSPM disclosed herein, according to some example embodiments. Exciting an electric field between two electrodes is one of the methods to obtain radio frequency (RF) gas discharge in a vacuum chamber. When an oscillating voltage is applied between the electrodes, the discharge obtained is referred to as a CCP discharge. In some embodiments, substrate processing stations disclosed herein may be based on the vacuum chamber 1300.

Plasma 1302 may be created within a processing zone 1330 of the vacuum chamber 1300 utilizing one or more process gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called reactive ion etch (RIE). In some aspects, the vacuum chamber 1300 may be used in connection with PECVD or PEALD deposition processes.

A controller 1316 manages the operation of the vacuum chamber 1300 by controlling the different elements in the chamber, such as RF generator 1318, gas sources 1322, and gas pump 1320. In one embodiment, fluorocarbon gases, such as CF₄ and C₄F₈, are used in a dielectric etch process for their anisotropic and selective etching capabilities, but the principles described herein may be applied to other plasma-creating gases. The fluorocarbon gases are readily dissociated into chemically reactive by-products that include smaller molecular and atomic radicals. These chemically reactive by-products etch away the dielectric material.

The vacuum chamber 1300 illustrates a processing chamber with multiple electrodes, such as an upper (or top) electrode 1304 and a lower (or bottom) electrode 1308. The upper electrode 1304 may be grounded or coupled to an RF generator (not shown), and the lower electrode 1308 is coupled to the RF generator 1318 via a matching network 1314. The RF generator 1318 provides an RF signal between the upper electrode 1304 and the lower electrode 1308 to generate RF power in one or multiple (e.g., two or three) different RF frequencies. According to the desired configuration of the vacuum chamber 1300 for a particular operation, at least one of the multiple RF frequencies may be turned ON or OFF. In the embodiment shown in FIG. 13, the RF generator 1318 is configured to provide at least three different frequencies, e.g., 400 kHz, 2 MHZ, 27 MHz, and 60 MHz, but other frequencies are also possible.

The vacuum chamber 1300 includes a gas showerhead on the top electrode 1304 to input process gas into the vacuum chamber 1300 provided by the gas source(s) 1322, and a perforated confinement ring 1312 that allows the gas to be pumped out of the vacuum chamber 1300 by gas pump 1320. In some example embodiments, the gas pump 1320 is a turbomolecular pump, but other types of gas pumps may be utilized.

When substrate 1306 is present in the vacuum chamber 1300, silicon focus ring 1310 is situated next to substrate 1306 such that there is a uniform RF field at the bottom surface of the plasma 1302 for uniform etching (or deposition) on the surface of the substrate 1306. The embodiment of FIG. 13 shows a triode reactor configuration where the top electrode 1304 is surrounded by a symmetric RF ground electrode 1324. Insulator 1326 is a dielectric that isolates the ground electrode 1324 from the top electrode 1304. Other implementations of the vacuum chamber 1300, including ICP-based implementations, are also possible without changing the scope of the disclosed embodiments.

As used herein, the term “substrate” indicates a support material upon which, or within which, elements of a semiconductor device are fabricated or attached. A substrate (e.g., substrate 1306) may include, for example, wafers (e.g., having a diameter of 100 mm, 150 mm, 200 mm, 300 mm, 450 mm, or larger) composed of, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied). Example substrates include blanket substrates and patterned substrates. A blanket substrate is a substrate that includes a low-surface (or planar) top surface. A patterned substrate is a substrate that includes a high-surface (or structured) top surface. A structured top surface of a substrate may include different high-surface-area structures such as 3D NAND memory holes or other structures.

Each frequency generated by the RF generator 1318 may be selected for a specific purpose in the substrate manufacturing process. In the example of FIG. 13, with RF powers provided at 400 kHz, 2 MHZ, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 1304 to get ultra-low energies and very high density. This configuration allows chamber cleaning with high-density plasma when substrate 1306 is not in the vacuum chamber 1300 while minimizing sputtering on the electrostatic chuck (ESC) surface. The ESC surface is exposed when substrate 1306 is not present, and any ion energy on the surface should be avoided, which is why the bottom 2 MHz and 27 MHz power supplies may be off during cleaning.

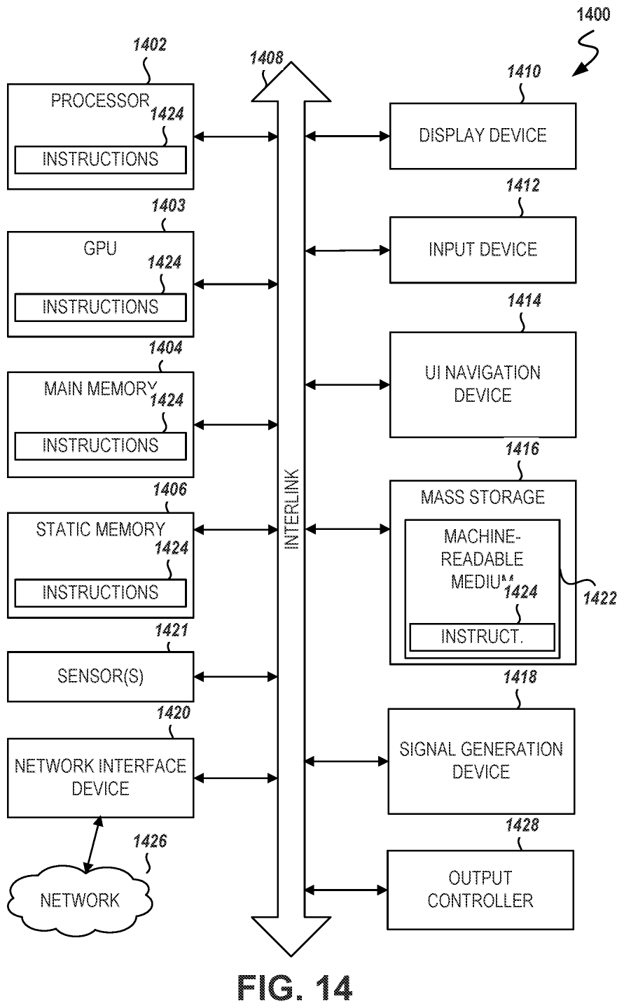

FIG. 14 is a block diagram illustrating an example of a machine 1400 upon or by which one or more example process embodiments described herein may be implemented or controlled. In alternative embodiments, the machine 1400 may operate as a standalone device or may be connected (e.g., networked) to other machines. In a networked deployment, the machine 1400 may operate in the capacity of a server machine, a client machine, or both in server-client network environments. In an example, the machine 1400 may act as a peer machine in a peer-to-peer (P2P) (or other distributed) network environment. Further, while only a single machine 1400 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1400 may include a hardware processor 1402 (e.g., a central processing unit (CPU), a hardware processor core, or any combination thereof), a graphics processing unit (GPU) 1403, a main memory 1404, and a static memory 1406, some or all of which may communicate with each other via an interlink (e.g., bus) 1408. The machine 1400 may further include a display device 1410, an alphanumeric input device 1412 (e.g., a keyboard), and a user interface (UI) navigation device 1414 (e.g., a mouse). In an example, the display device 1410, alphanumeric input device 1412, and UI navigation device 1414 may be a touch screen display. The machine 1400 may additionally include a mass storage device (e.g., drive unit) 1416, a signal generation device 1418 (e.g., a speaker), a network interface device 1420, and one or more sensors 1421, such as a Global Positioning System (GPS) sensor, compass, accelerometer, or another sensor. The machine 1400 may include an output controller 1428, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1402 may perform the functionalities of the controller 1316 discussed hereinabove, in connection with at least FIG. 13. In some embodiments, the hardware processor 1402 is configured to control functionalities of one or more MSPMs discussed herein (e.g., as a controller of an individual MSPM, as a controller of an individual substrate processing station, as a controller of a substrate processing tool that includes multiple MSPMs, or a combination thereof).

The mass storage device 1416 may include a machine-readable medium 1422 on which is stored one or more sets of data structures or instructions 1424 (e.g., software) embodying or utilized by any one or more of the techniques or functions described herein. The instructions 1424 may also reside, completely or at least partially, within the main memory 1404, within the static memory 1406, within the hardware processor 1402, or within the GPU 1403 during execution thereof by the machine 1400. In an example, one or any combination of the hardware processor 1402, the GPU 1403, the main memory 1404, the static memory 1406, or the mass storage device 1416 may constitute machine-readable media.

While the machine-readable medium 1422 is illustrated as a single medium, the term “machine-readable medium” may include a single medium or multiple media, (e.g., a centralized or distributed database, and/or associated caches and servers) configured to store the one or more instructions 1424.

The term “machine-readable medium” may include any medium that is capable of storing, encoding, or carrying instructions 1424 for execution by the machine 1400 and that cause the machine 1400 to perform any one or more of the techniques of the present disclosure, or that is capable of storing, encoding, or carrying data structures used by or associated with such instructions 1424. Non-limiting machine-readable medium examples may include solid-state memories and optical and magnetic media. In an example, a massed machine-readable medium comprises a machine-readable medium 1422 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1424 may further be transmitted or received over a communications network 1426 using a transmission medium via the network interface device 1420.

Implementation of the preceding techniques may be accomplished through any number of specifications, configurations, or example deployments of hardware and software. It should be understood that the functional units or capabilities described in this specification may have been referred to or labeled as components or modules, to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### Additional Notes and Examples

Example 1 is a multi-station processing module for processing substrates, the multi-station processing module comprising: at least one substrate handoff station arranged in a first transfer plane, the at least one substrate handoff station configured to perform a handoff of at least one substrate of a plurality of substrates; a plurality of substrate processing stations arranged in a second transfer plane around a substrate transfer region, the second transfer plane arranged parallel to and offset from the first transfer plane, and each of the plurality of substrate processing stations configured to process one or more of the plurality of substrates; and a robot arranged in the substrate transfer region, the robot configured to move the one or more of the plurality of substrates between the first transfer plane and the second transfer plane during the handoff.

In Example 2, the subject matter of Example 1 includes subject matter where the robot is configured to move the one or more of the plurality of substrates between the at least one substrate handoff station and the plurality of substrate processing stations via a corresponding plurality of substrate passthrough slots.

In Example 3, the subject matter of Example 2 includes subject matter where the robot is configured to horizontally move the one or more of the plurality of substrates within a first substrate passthrough slot of the plurality of substrate passthrough slots, the first substrate passthrough slot disposed in the first transfer plane, between the at least one substrate handoff station and a vertical passageway of the substrate transfer region.

In Example 4, the subject matter of Example 3 includes subject matter where the robot is configured to vertically move the one or more of the plurality of substrates from the first transfer plane to at least one of the plurality of substrate processing stations in the second transfer plane using the vertical passageway and at least a second substrate passthrough slot of the plurality of substrate passthrough slots, the at least a second substrate passthrough slot disposed in the second transfer plane.

In Example 5, the subject matter of Examples 1-4 includes subject matter where the at least one substrate handoff station is configured to perform the handoff during the processing of the one or more of the plurality of substrates by at least one of the plurality of substrate processing stations.

In Example 6, the subject matter of Examples 1-5 includes subject matter where the plurality of substrate processing stations comprises a corresponding plurality of substantially axisymmetric body portions.

In Example 7, the subject matter of Example 6 includes subject matter where the plurality of substantially axisymmetric body portions are isolated from each other via at least one purging gas curtain.

In Example 8, the subject matter of Examples 1-7 includes, a sliding arrangement disposed in the first transfer plane, the sliding arrangement configured to move the second transfer plane in a vertical and horizontal direction in relation to the first transfer plane.

In Example 9, the subject matter of Examples 1-8 includes subject matter where the at least one substrate handoff station comprises a substrate handoff station and a pre-processing station arranged in the first transfer plane, the substrate handoff station configured to perform the handoff of the at least one substrate of the plurality of substrates.

In Example 10, the subject matter of Example 9 includes subject matter where the pre-processing station is configured to perform pre-processing of the plurality of substrates, the pre-processing comprising at least one of pre-cleaning or pre-heating of the plurality of substrates.

In Example 11, the subject matter of Examples 1-10 includes subject matter where the at least one substrate handoff station comprises at least one pre-processing station and at least one post-processing station, wherein: the at least one pre-processing station is configured to perform pre-processing of the plurality of substrates, the pre-processing comprising degassing, pre-cleaning or pre-heating of the plurality of substrates; and the at least one post-processing station is configured to perform post-processing of the plurality of substrates, the post-processing comprising performing a cooling down or annealing.

In Example 12, the subject matter of Examples 1-11 includes subject matter where the plurality of substrates comprises a plurality of semiconductor wafers.

In Example 13, the subject matter of Examples 1-12 includes subject matter where the plurality of substrate processing stations are configured to process the one or more of the plurality of substrates while performing a same deposition or etching process.

In Example 14, the subject matter of Examples 1-13 includes subject matter where the plurality of substrate processing stations are configured to process the one or more of the plurality of substrates while performing different deposition or etching processes.

In Example 15, the subject matter of Examples 1-14 includes subject matter where the plurality of substrate processing stations are symmetrically arranged around the substrate transfer region.

In Example 16, the subject matter of Examples 1-15 includes subject matter where the plurality of substrate processing stations are asymmetrically arranged around the substrate transfer region.

Example 17 is a substrate processing tool comprising: a vacuum transfer module; and a plurality of multi-station processing modules for processing substrates received from the vacuum transfer module, the plurality of multi-station processing modules arranged along an outside perimeter of the vacuum transfer module, and each of the plurality of multi-station processing modules comprising: at least one substrate handoff station arranged in a first transfer plane, the at least one substrate handoff station configured to perform a handoff of at least one substrate of a plurality of substrates received from the vacuum transfer module; a plurality of substrate processing stations arranged in a second transfer plane around a substrate transfer region, each of the plurality of substrate processing stations configured to process one or more of the plurality of substrates; and a robot arranged in the substrate transfer region, the robot configured to move the one or more of the plurality of substrates between the at least one substrate handoff station and the plurality of substrate processing stations during the handoff.

In Example 18, the subject matter of Example 17 includes subject matter where the vacuum transfer module further comprises a second robot, the second robot configured to handoff the at least one substrate to the at least one substrate handoff station; and retrieve the at least one substrate from the at least one substrate handoff station after processing of the at least one substrate by at least one of the plurality of substrate processing stations.

In Example 19, the subject matter of Examples 17-18 includes subject matter where the vacuum transfer module further comprises at least one pre-processing station and at least one post-processing station.

In Example 20, the subject matter of Examples 17-19 includes subject matter where the first transfer plane and the second transfer plane are coincident with each other.

In Example 21, the subject matter of Examples 17-20 includes subject matter where the second transfer plane is arranged parallel to and offset from the first transfer plane.

Example 22 is a multi-station processing module for processing substrates, the multi-station processing module comprising: at least one substrate handoff station arranged in a first transfer plane, the at least one substrate handoff station configured to perform a handoff of at least one substrate of a plurality of substrates; a plurality of substrate processing stations arranged in a second transfer plane around a substrate transfer region, each of the plurality of substrate processing stations configured to process one or more of the plurality of substrates using a substantially axisymmetric body portion; and a robot arranged in the substrate transfer region, the robot configured to move the one or more of the plurality of substrates between the at least one substrate handoff station and the plurality of substrate processing stations during the handoff.

In Example 23, the subject matter of Example 22 includes subject matter where the first transfer plane and the second transfer plane are coincident with each other.

In Example 24, the subject matter of Examples 22-23 includes subject matter where the second transfer plane is arranged parallel to and offset from the first transfer plane.

In Example 25, the subject matter of Example 24 includes, a sliding arrangement disposed in the first transfer plane, the sliding arrangement configured to move the second transfer plane in a vertical and horizontal direction in relation to the first transfer plane.

Example 26 is at least one machine-readable medium including instructions that, when executed by processing circuitry, cause the processing circuitry to perform operations to implement any of Examples 1-25.

Example 27 is an apparatus comprising means to implement any of Examples 1-25.

Example 28 is a system to implement any of Examples 1-25.

Example 29 is a method to implement any of Examples 1-25.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionalities presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A multi-station processing module for processing substrates, the multi-station processing module comprising:
at least one substrate handoff station arranged in a first transfer plane, the at least one substrate handoff station configured to perform a handoff of at least one substrate of a plurality of substrates;
a plurality of substrate processing stations arranged in a second transfer plane around a substrate transfer region, the second transfer plane arranged parallel to and offset from the first transfer plane, and each of the plurality of substrate processing stations configured to process one or more of the plurality of substrates; and
a robot arranged in the substrate transfer region, the robot configured to move the one or more of the plurality of substrates between the first transfer plane and the second transfer plane during the handoff.

2. The multi-station processing module of claim 1, wherein the robot is configured to move the one or more of the plurality of substrates between the at least one substrate handoff station and the plurality of substrate processing stations via a corresponding plurality of substrate passthrough slots.

3. The multi-station processing module of claim 2, wherein the robot is configured to horizontally move the one or more of the plurality of substrates within a first substrate passthrough slot of the plurality of substrate passthrough slots, the first substrate passthrough slot disposed in the first transfer plane, between the at least one substrate handoff station and a vertical passageway of the substrate transfer region.

4. The multi-station processing module of claim 3, wherein the robot is configured to vertically move the one or more of the plurality of substrates from the first transfer plane to at least one of the plurality of substrate processing stations in the second transfer plane using the vertical passageway and at least a second substrate passthrough slot of the plurality of substrate passthrough slots, the at least a second substrate passthrough slot disposed in the second transfer plane.

5. The multi-station processing module of claim 1, wherein the at least one substrate handoff station is configured to perform the handoff during processing of the one or more of the plurality of substrates by at least one of the plurality of substrate processing stations.

6. The multi-station processing module of claim 1, wherein the plurality of substrate processing stations comprise a corresponding plurality of substantially axisymmetric body portions.

7. The multi-station processing module of claim 6, wherein the plurality of substantially axisymmetric body portions are isolated from each other via at least one purging gas curtain.

8. The multi-station processing module of claim 1, further comprising:
a sliding arrangement disposed in the first transfer plane, the sliding arrangement configured to move the second transfer plane in a vertical and horizontal direction in relation to the first transfer plane.

9. The multi-station processing module of claim 1, wherein the at least one substrate handoff station comprises a substrate handoff station and a pre-processing station arranged in the first transfer plane, the substrate handoff station configured to perform the handoff of the at least one substrate of the plurality of substrates.

10. The multi-station processing module of claim 9, wherein the pre-processing station is configured to perform pre-processing of the plurality of substrates, the pre-processing comprising at least one of pre-cleaning or pre-heating of the plurality of substrates.

11. The multi-station processing module of claim 1, wherein the at least one substrate handoff station comprises at least one pre-processing station and at least one post-processing station, wherein:
the at least one pre-processing station is configured to perform pre-processing of the plurality of substrates, the pre-processing comprising degassing, pre-cleaning, or pre-heating of the plurality of substrates; and
the at least one post-processing station is configured to perform post-processing of the plurality of substrates, the post-processing comprising performing a cooling down or annealing.

12. The multi-station processing module of claim 1, wherein the plurality of substrates comprises a plurality of semiconductor wafers.

13. The multi-station processing module of claim 1, wherein the plurality of substrate processing stations are configured to process the one or more of the plurality of substrates while performing a same deposition or etching process.

14. The multi-station processing module of claim 1, wherein the plurality of substrate processing stations are configured to process the one or more of the plurality of substrates while performing different deposition or etching processes.

15. The multi-station processing module of claim 1, wherein the plurality of substrate processing stations are symmetrically arranged around the substrate transfer region.

16. The multi-station processing module of claim 1, wherein the plurality of substrate processing stations are asymmetrically arranged around the substrate transfer region.

17. A substrate processing tool comprising:
a vacuum transfer module; and
a plurality of multi-station processing modules for processing substrates received from the vacuum transfer module, the plurality of multi-station processing modules arranged along an outside perimeter of the vacuum transfer module, and each of the plurality of multi-station processing modules comprising:
at least one substrate handoff station arranged in a first transfer plane, the at least one substrate handoff station configured to perform a handoff of at least one substrate of a plurality of substrates received from the vacuum transfer module;
a plurality of substrate processing stations arranged in a second transfer plane around a substrate transfer region, each of the plurality of substrate processing stations configured to process one or more of the plurality of substrates; and
a robot arranged in the substrate transfer region, the robot configured to move the one or more of the plurality of substrates between the at least one substrate handoff station and the plurality of substrate processing stations during the handoff.

18. The substrate processing tool of claim 17, wherein the vacuum transfer module further comprises a second robot, the second robot configured to:
handoff the at least one substrate to the at least one substrate handoff station; and
retrieve the at least one substrate from the at least one substrate handoff station after processing the at least one substrate by at least one of the plurality of substrate processing stations.

19. The substrate processing tool of claim 17, wherein the vacuum transfer module further comprises at least one pre-processing station and at least one post-processing station, wherein:
the at least one pre-processing station is configured to perform pre-processing of the plurality of substrates, the pre-processing comprising degassing, pre-cleaning, or pre-heating of the plurality of substrates; and
the at least one post-processing station is configured to perform post-processing of the plurality of substrates, the post-processing comprising performing a cooling down or annealing.

20. The substrate processing tool of claim 17, wherein the first transfer plane and the second transfer plane are coincident with each other.

21. The substrate processing tool of claim 17, wherein the second transfer plane is arranged parallel to and offset from the first transfer plane.

22. A multi-station processing module for processing substrates, the multi-station processing module comprising:
at least one substrate handoff station arranged in a first transfer plane, the at least one substrate handoff station configured to perform a handoff of at least one substrate of a plurality of substrates;
a plurality of substrate processing stations arranged in a second transfer plane around a substrate transfer region, each of the plurality of substrate processing stations configured to process one or more of the plurality of substrates using a substantially axisymmetric body portion; and
a robot arranged in the substrate transfer region, the robot configured to move the one or more of the plurality of substrates between the at least one substrate handoff station and the plurality of substrate processing stations during the handoff.

23. The multi-station processing module of claim 22, wherein the first transfer plane and the second transfer plane are coincident with each other.

24. The multi-station processing module of claim 22, wherein the second transfer plane is arranged parallel to and offset from the first transfer plane.

25. The multi-station processing module of claim 24, further comprising:
a sliding arrangement disposed in the first transfer plane, the sliding arrangement configured to move the second transfer plane in a vertical and horizontal direction in relation to the first transfer plane.
